(19) United States
(12) Patent Application Publication
(10) Pub. No.: US 2005/0012176 A1
(43) Pub. Date: Jan. 20, 2005

(54) Electromagnetic device and method of operating the same

(76) Inventor: Torkel Arnborg, Stockholm (SE)

Correspondence Address: Andreas Grubert;Baker Botts L.L.P., One Shell Plaza, 910 Louisiana, Houston, TX, 77002-4995, US

(21) Appl. No.: 10/872,604

(22) Filed: Jun. 21, 2004

(30) Foreign Application Priority Data
Jul. 18, 2003 (SE) 0302107-8

(51) Int. Cl. H01L 29/76; H01L 31/062

(52) U.S. Cl. 257/531; 257/379

(57) ABSTRACT

An electromagnetic device in an integrated circuit, particularly an integrated circuit for radio frequency applications, comprises a MOS transistor structure (11; 11′) and a spiral inductor (12; 12, 41). The MOS transistor structure and the spiral inductor are arranged on top of each other to obtain an operative coupling between a MOS current (17; 23a-b) of the MOS transistor structure and a magnetic field (16) of the spiral inductor via the Hall effect, and an electric input (14, 15) is provided for controlling an electric quantity of either one of the MOS transistor structure and the spiral inductor in order to influence the operation of the other one of the MOS transistor structure and the spiral inductor via the operative coupling. The device may be used in a large variety of applications for obtaining various functions. A method of operating the electromagnetic device is also disclosed.

### PRIORITY

This application claims priority to Swedish application no. 0302107-8 filed Jul. 18, 2003.

### TECHNICAL FIELD OF THE INVENTION

The present invention generally relates to the field of integrated circuit technology, and more specifically the invention relates to a monolithically integrated electromagnetic device, and to a method of operating such an electromagnetic device.

### DESCRIPTION OF RELATED ART AND BACKGROUND OF THE INVENTION

Integrated inductors have found widespread use in integrated circuits for RF (radio frequency) applications. They occupy quite much space, where typically no other circuit elements can be located.

Integrated RF circuits are usually implemented with RLC type of elements in a design style that has been inherited from solutions with discrete devices on printed circuit boards. The main difference is that integrated circuit devices have some quite different data, especially concerning figures-of-merit and cross-couplings.

Integrated inductors have been difficult to design due to lack of simulation tools and understanding of electromagnetic interaction with the substrate. Therefore, the inductors have been localized in areas separated from devices to avoid interference. However, such design may result in bulky and thus slow devices.

### SUMMARY OF THE INVENTION

It is an object of the present invention to provide an electromagnetic device in an integrated circuit, particularly an integrated circuit for radio frequency applications, which overcomes the problems associated with the prior art.

It is thus a particular object of the invention to provide such an electromagnetic device, by which new design rules for integrated circuits can be employed, which will result in area and possibly speed loss of the devices fabricated.

It is a further object of the invention to provide a method of operating such an electromagnetic device.

These objects can be attained, according to the present invention, by an electromagnetic device in an integrated circuit, particularly an integrated circuit for radio frequency applications, comprising an MOS transistor structure and a spiral inductor, wherein the MOS transistor structure and the spiral inductor are arranged on top of each other to obtain an operative coupling between a MOS current of the MOS transistor structure and a magnetic field of the spiral inductor via the Hall effect, and an electric input is provided for controlling an electric quantity of a first one of the MOS transistor structure and the spiral inductor in order to influence the operation of the second one of the MOS transistor structure and the spiral inductor via the operative coupling.

The electric input can be provided for controlling an electric quantity of the MOS transistor structure in order to influence the operation of the spiral inductor via the operative coupling. The electric quantity can be a gate voltage of the MOS transistor structure. The electric input can be provided for influencing the Q value of the spiral inductor via the operative coupling. The electric input can be provided for influencing the inductance of the spiral inductor via the operative coupling. The electric input can be provided for controlling an electric quantity of the spiral inductor in order to influence the operation of the MOS transistor structure via the operative coupling. The electric quantity can be a current in the spiral inductor. The electric input can be provided for influencing a MOS current of the MOS transistor structure. The MOS transistor structure may comprise a split drain structure including two separated drains, and the electric input can be provided for influencing a differential current through the two separated drains. The electromagnetic device can be provided for operating as an amplifier having a current in the spiral inductor as input and the differential current through the two separated drains as output.

The objects can also be attained by a method of operating an integrated circuit based electromagnetic device comprising an MOS transistor structure and a spiral inductor, comprising the steps of:
operatively, via the Hall effect, coupling a magnetic field of the spiral inductor to a MOS current of the MOS transistor structure, and
controlling an electric quantity of a first one of the MOS transistor structure and the spiral inductor in order to influence, via the operative coupling, the operation of the second one of the MOS transistor structure and the spiral inductor.

The method may further comprise the step of controlling an electric quantity of the MOS transistor structure in order to influence the operation of the spiral inductor via the operative coupling. The method may further comprise the step of influencing a Q value of the spiral inductor via the operative coupling. The method may further comprise the step of influencing the inductance of the spiral inductor via the operative coupling. The method may further comprise the step of controlling an electric quantity of the spiral inductor in order to influence the operation of the MOS transistor structure via the operative coupling. The method may further comprise the step of influencing an MOS current of the MOS transistor structure.

By providing a MOS transistor structure and a spiral inductor on top of each other to obtain an operative coupling between a MOS current of the MOS transistor structure and a magnetic field of the spiral inductor via the Hall effect, and by controlling an electric quantity of a first one of the MOS transistor structure and the spiral inductor in order to influence the operation of the second one of the MOS transistor structure and the spiral inductor via the operative coupling, an electromagnetic device is achieved, which occupies less space and by use of which faster integrated circuits can be fabricated.

In case of controlling an electric quantity of the MOS transistor structure in order to influence the operation of the spiral inductor, the electric quantity is advantageously a gate voltage of the MOS transistor structure, by which the Q value or the inductance of the spiral inductor can be controlled.

In case of controlling an electric quantity of the spiral inductor in order to influence the operation of the MOS transistor structure, the electric quantity is advantageously the current flown in the spiral inductor, or the magnetic field created by the spiral inductor, by which a MOS current of the MOS transistor structure can be controlled.

The electromagnetic device of the present invention can be used in a variety of devices such as e.g. inductors, amplifiers, VCO's, mixers, and modulators.

Further characteristics of the invention and advantages thereof will be evident from the detailed description of preferred embodiments of the present invention given hereinafter and the accompanying FIGS. 1-4, which are given by way of illustration only, and thus are not limitative of the present invention.

### BRIEF DESCRIPTION OF THE DRAWINGS

FIG. 1 is a highly enlarged schematic perspective view of an electromagnetic device according to a preferred embodiment of the present invention.

FIG. 2 is a highly enlarged schematic perspective view of an electromagnetic device according to a further preferred embodiment of the invention.

FIG. 3 is a highly enlarged schematic top view of part of the electromagnetic device of FIG. 2.

FIG. 4 is a schematic circuit layout of an electromagnetic device according to still a further preferred embodiment of the invention.

### DETAILED DESCRIPTION OF PREFERRED EMBODIMENTS

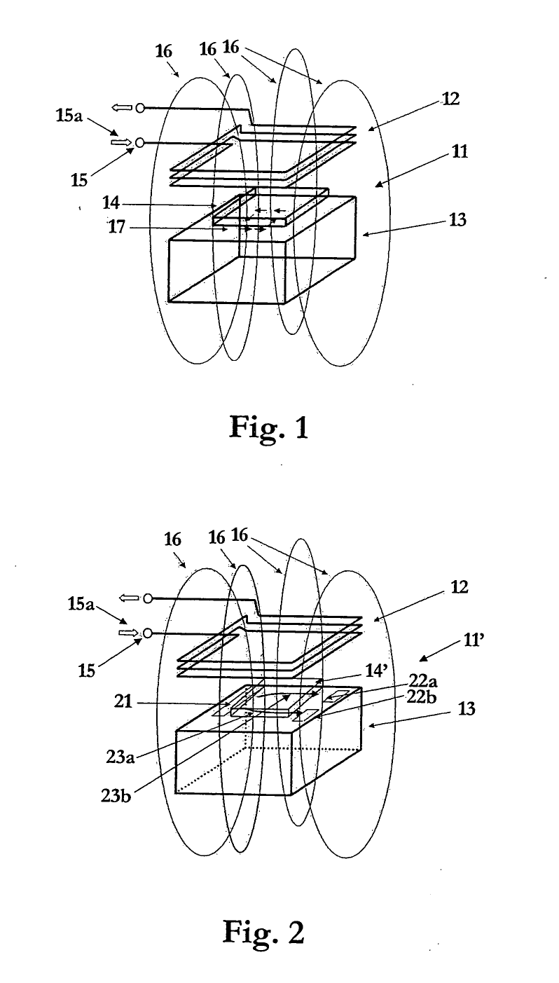

In FIG. 1 a monolithically integrated electromagnetic device according to a first preferred embodiment of the present invention is schematically shown. The electromagnetic device, which is especially aimed for RF applications, comprises a MOS transistor structure 11 and a spiral inductor 12 arranged on top of each other on a semiconductor, preferably silicon, chip substrate 14. The MOS structure 11 comprises a MOS gate 14, preferably of polycrystalline silicon, but advantageously no source or drain.

By this arrangement an operative electromagnetic coupling between the two devices is obtained. A current 15a fed to an input 15 of the spiral inductor 12 is flown through the spiral inductor 12, and gives rise to a magnetic field 16, whose field lines penetrates through the MOS structure 11 and its gate 14.

Assuming a skin depth large enough, a circular current 17 similar to the current in the spiral inductor 12 but with opposite direction will be induced in the MOS transistor structure. The electrons are generated from the thermal Shockley-Read-Hall process provided that no source or drain exists. When the voltage of the gate 14 is increased, the surface is inverted and the circular current will increase. A result of this is that the spiral inductor 12 obtains higher losses, that is a higher Q-value.

The magnetic field 16 is thus operatively coupled to the MOS current 17 of the MOS structure 11 via the Hall effect. Generally, by controlling an electric quantity of the MOS transistor structure, e.g. the gate voltage, the operation of the spiral inductor, e.g. its Q value or its inductance, can be influenced and controlled via the operative Hall effect coupling.

In FIG. 2 a monolithically integrated electromagnetic device according to a second preferred embodiment of the present invention is schematically shown. Here, the spiral inductor is arranged above a modified MOS transistor structure denoted 11′. The modified MOS transistor structure 11′ has a gate 14′, a source 21 and a split drain structure 22a-b of the same type that is used in Hall detectors, i.e. including two separated drains 22a, 22b.

By feeding a current 15a to the input 15 of the spiral inductor 12 and flowing this current through the spiral inductor 12 a magnetic field 16 is created above and within the MOS transistor structure 11′. A MOS current from the source 21 to the split drain structure 22a-b will be deflected due to the Hall effect towards one of the drains 22a, 22b depending on the direction of the magnetic field. This is schematically indicated by the two arrows 23a, 23b.

It is important to have an appropriate coupling strength between the magnetic field 16 and the induced MOS current 17. Sensitivities of about 1 V/T have been reported for CMOS based Hall effect sensors.

From the basic theory of electromagnetism one has
B=φ/A, (1)
where B is the magnetic flux density [Vs/m²], φ is the magnetic flux, and A is the area. Further, [symbol]
Hds=N×I, (2)
where H is the magnetizing flux, N is the number of turns of the spiral inductor, and I is the current flown through the spiral inductor. Still further,
B=μ₀H (3)
where μ₀ is the permeability, i.e. about 4π10⁻⁷ Vs/A/m=1.2 10⁻⁶H/m, and
Φ=L×I, (4)
where L is the inductance of the spiral inductor.

For a wire having a radius a, the magnetic flux density is given by

$$B = \frac{{μμ}_{0} N \times 1}{2 \prod a} = {2.10}^{- 7} \frac{N \times I}{a} \qquad ( 5 )$$

Typical values for an integrated spiral inductor, I=100 mA, N=5 turns, a=10 microns, will give a magnetic field B of about 0.01 Tesla and about 10 mV between the two drains for the typical sensitivity of a Hall effect CMOS sensor.

Note that the magnetic flux density is proportional to the current and the number of turns as well as inversely proportional to the radius of the inductor. This means that a scaled electromagnetic RF device of the present invention follows the general scaling rules for VLSI. A major trend today is a reduction of feature sizes and an increase of the number of metal layers. This makes the invention even more relevant for future technologies.

The electromagnetic device of FIG. 2 can be used as an amplifier, where the input is the current 15a in the spiral inductor 12 and the output is the differential current 23b-23a of the two drains 22a, 22b of the MOS transistor structure 11′. Alternatively, the device may be used in VCO's, mixers, or modulators.

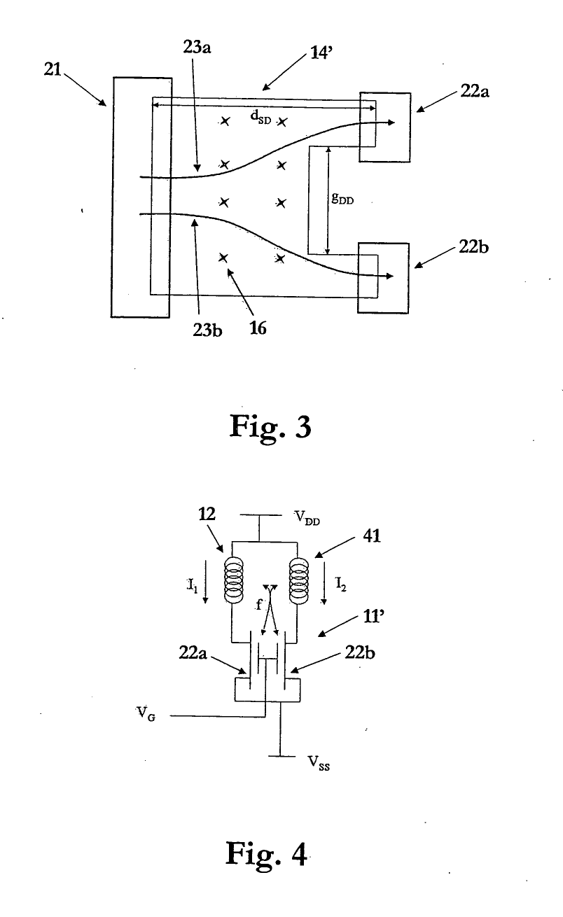

The design of the split drain MOS transistor is illustrated in FIG. 3, wherein the magnetic field 16 produced by the spiral inductor is indicated. The design is important for the final result. The distance dSD between the source 21 and the two drains 22a, 22bb should be kept small for RF operation, which is in contrast to low frequency devices, which include DC Hall sensors. Further, the gap gDD between the two drains 22a, 22b must be chosen large to get a reasonable selectivity without loosing speed.

Still further, a proper geometry will affect the linearity between differential output current and applied magnetic field. For variable Q and variable inductance devices, amplifiers, and mixers the linearity should be high. For mixers it should be high. For oscillators it depends on the application, but usually high linearity is desired.

In FIG. 4 a schematic equivalent circuit layout of an electromagnetic device according to still a further preferred embodiment of the invention is shown. This device is similar to the device of FIG. 2, but a second spiral inductor 41 is provided parallel with and very close to the existing first spiral inductor 12. However, a current 12 in the second spiral inductor 41 is flowed in an opposite direction as compared with a current I₁ in the first spiral inductor 12. In FIG. 4, Vdd denotes the drain supply voltage, Vg denotes the gate voltage, Vss denotes the source supply voltage, 11 and 12 denote the currents through the two respective drains 22a, 22b, and f denotes the coupling factor between the magnetic field of the spiral inductors 12, 41 and the drain currents 11, 12.

The drain currents 11 and 12 are given by the following equations:
I_{D1}=β(V_{G}−V_{T})V_{D1}F(I₁−I₂)) (6)
I_{D2}=β(V_{G}−V_{T})V_{D2}F(I₂−I₁)) (7)
where V_{D1} and V_{D2} are drain voltages on the two respective drains 22a, 22b.

By using appropriate dimensions of the device of FIG. 4 a VCO or a mixer can be realized. For the VCO the circuit should be made unstable and possibly, a further phase shifting network may be needed. For the mixer radio frequency (RF), intermediate frequency (IF) and low frequency (LF) inputs/outputs are needed.

The electromagnetic device of the present invention will offer a new coupling mechanism that might be very useful in RF-IC design. MOS circuits, which already contain inductors and transistors, have RF building blocks that require several connections to perform desired operations. Areas for inductors, previously unused for other purposes, will according to the invention contain transistors, by which higher packing density and thus smaller and faster circuits can be achieved. The characteristics of the new coupling mechanism between a magnetic flux of a spiral inductor and a MOS current of a MOS transistor structure can be employed in a large range of building blocks.

It shall be appreciated that while the present invention is primarily intended for silicon based RF integrated circuits, it may nevertheless be realized in other material systems such as e.g. GaAs and/or for other kind of applications.

1. An electromagnetic device in an integrated circuit, particularly an integrated circuit for radio frequency applications, comprising an MOS transistor structure and a spiral inductor, wherein
said MOS transistor structure and said spiral inductor are arranged on top of each other to obtain an operative coupling between a MOS current of said MOS transistor structure and a magnetic field of said spiral inductor via the Hall effect, and
an electric input is provided for controlling an electric quantity of a first one of said MOS transistor structure and said spiral inductor in order to influence the operation of the second one of said MOS transistor structure and said spiral inductor via said operative coupling.

2. The electromagnetic device of claim 1, wherein said electric input is provided for controlling an electric quantity of said MOS transistor structure in order to influence the operation of said spiral inductor via said operative coupling.

3. The electromagnetic device of claim 2, wherein said electric quantity is a gate voltage of said MOS transistor structure.

4. The electromagnetic device of claim 2, wherein said electric input is provided for influencing the Q value of said spiral inductor via said operative coupling.

5. The electromagnetic device of claim 3, wherein said electric input is provided for influencing the Q value of said spiral inductor via said operative coupling.

6. The electromagnetic device of claim 2, wherein said electric input is provided for influencing the inductance of said spiral inductor via said operative coupling.

7. The electromagnetic device of claim 3, wherein said electric input is provided for influencing the inductance of said spiral inductor via said operative coupling.

8. The electromagnetic device of claim 1, wherein said electric input is provided for controlling an electric quantity of said spiral inductor in order to influence the operation of said MOS transistor structure via said operative coupling.

9. The electromagnetic device of claim 8, wherein said electric quantity is a current in said spiral inductor.

10. The electromagnetic device of claim 8, wherein said electric input is provided for influencing a MOS current of said MOS transistor structure.

11. The electromagnetic device of claim 9, wherein said electric input is provided for influencing a MOS current of said MOS transistor structure.

12. The electromagnetic device of claim 10, wherein said MOS transistor structure comprises a split drain structure including two separated drains, and said electric input is provided for influencing a differential current through said two separated drains.

13. The electromagnetic device of claim 11, wherein said MOS transistor structure comprises a split drain structure including two separated drains, and said electric input is provided for influencing a differential current through said two separated drains.

14. The electromagnetic device of claim 12, wherein said electromagnetic device is provided for operating as an amplifier having a current in said spiral inductor as input and said differential current through said two separated drains as output.

15. The electromagnetic device of claim 13, wherein said electromagnetic device is provided for operating as an amplifier having a current in said spiral inductor as input and said differential current through said two separated drains as output.

16. A method of operating an integrated circuit based electromagnetic device comprising an MOS transistor structure and a spiral inductor, comprising the steps of:
operatively, via the Hall effect, coupling a magnetic field of said spiral inductor to a MOS current of said MOS transistor structure, and
controlling an electric quantity of a first one of said MOS transistor structure and said spiral inductor in order to influence, via said operative coupling, the operation of the second one of said MOS transistor structure and said spiral inductor.

17. The method of claim 16, further comprising the step of controlling an electric quantity of said MOS transistor structure in order to influence the operation of said spiral inductor via said operative coupling.

18. The method of claim 16, further comprising the step of influencing a Q value of said spiral inductor via said operative coupling.

19. The method of claim 16, further comprising the step of influencing the inductance of said spiral inductor via said operative coupling.

20. The method of claim 16, further comprising the step of controlling an electric quantity of said spiral inductor in order to influence the operation of said MOS transistor structure via said operative coupling.

21. The method of claim 16, further comprising the step of influencing an MOS current of said MOS transistor structure.
